(19) United States
(12) Patent Application Publication
(10) Pub. No.: US 2013/0334699 A1
(43) Pub. Date: Dec. 19, 2013

(54) SEMICONDUCTOR DEVICE AND FABRICATING METHOD THEREOF

(71) Applicants: Chien-Li Kuo, Hsinchu City (TW); Yung-Chang Lin, Taichung City (TW)

(72) Inventors: Chien-Li Kuo, Hsinchu City (TW); Yung-Chang Lin, Taichung City (TW)

(21) Appl. No.: 13/526,546

(22) Filed: Jun. 19, 2012

(51) Int. Cl. H01L 23/498; H01L 21/768

(52) U.S. Cl. 257/774; 438/653; 257/E23.067; 257/E21.584

(57) ABSTRACT

A semiconductor device includes a substrate with a front side and a back side, an ILD, disposed on the substrate, a cap layer disposed on the backside of the substrate, a TSV penetrating the cap layer, the substrate and the ILD, wherein a cap layer sidewall in the TSV juts out beyond the substrate sidewall the TSV with a predetermined distance, and a liner is disposed on the substrate sidewall, wherein the liner partially overlaps with the cap layer.

### BACKGROUND OF THE INVENTION

1. Field of the Invention

The present invention relates to a semiconductor device, and more particularly, a semiconductor device comprising a TSV.

2. Description of the Prior Art

Nowadays, micro-processor systems including integrated circuits (IC) are polyvalent devices and are used in diverse application fields, such as automatic control electronics, mobile communication devices and personal computers. With the development of technology and the increasingly imaginative applications of electrical products, the IC devices are increasingly smaller, more precise and more polyvalent.

As known in the art, IC devices are produced from dies that are fabricated through conventional semiconductor manufacturing processes. A process to manufacture a die starts with a wafer: first, different regions are marked on the wafer; then conventional semiconductor manufacture processes, such as deposition, photolithography, etching or planarization, are carried out to form required circuit traces; then each region of the wafer is separated to form a die and packaged to form a chip; finally, the chips are attached onto boards, for example printed circuit boards (PCB), and the chips are electrically coupled to the pins on the PCB. Thus, each of the programs on the chip can be performed.

In order to evaluate the functions and the efficiency of a chip and increase the capacitance density in order to contain more IC components in a limited space, many semiconductor packages are built up by stacking the dies and/or chips through, for example, Flip-Chip technology, Multi-chip Package (MCP) technology, Package on Package (PoP) technology and Package in Package (PiP) technology. Besides these technologies, a “Through Silicon Via (TSV)” technique has been well developed in recent years. The TSV can improve the interconnections between the dies in the package so as to increase the package efficiency.

The first step to fabricate a TSV is to form a via on a wafer through an etching or a laser process, then fill the via with copper, polycrystalline silicon, tungsten, or other conductive materials; then, the chips are thinned and packaged or bonded to form a 3D package structure. When using the TSV technique, the interconnection route between the chips is shorter. Thus, in comparison to other technologies, the TSV has the advantages of faster speed, less noise and better efficiency, and therefore looks set to become one of the most popular technologies in the future.

### SUMMARY OF THE INVENTION

According to one embodiment of the present invention, a semiconductor device is provided comprising a substrate with a front surface and a back surface; an ILD (inter layer dielectric) disposed on the front surface; a cap layer disposed on the back surface; a TSV (through silicon via) penetrating the cap layer, the substrate and the ILD, wherein the TSV has a cap layer sidewall and a substrate sidewall, wherein the cap layer sidewall juts out beyond the substrate sidewall with a predetermined distance; and a liner disposed on the substrate sidewall in the TSV, wherein the liner overlaps parts of the cap layer.

The present invention provides a manufacturing method of a semiconductor device, comprising the following steps: first, a substrate with a front surface and a back surface is provided; then, an ILD (inter layer dielectric) is formed on the front surface ; then, a cap layer is formed on the back surface; an opening is formed on the back surface of the substrate penetrating the cap layer and the substrate, wherein the opening has a cap layer sidewall and a substrate sidewall, and the cap layer sidewall juts out beyond the substrate sidewall with a predetermined distance; then, a liner is selectively formed on the substrate sidewall, and the liner overlaps parts of the cap layer; the ILD is etched through the opening to form a TSV hole penetrating the ILD; and a conductive layer is formed in the TSV hole.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 are schematic, cross-sectional diagrams illustrating a method for fabricating a semiconductor device in accordance with the first preferred embodiment of the invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and effects to be achieved.

Please note that the figures are only for illustration and the figures may not be to scale. The scale may be further modified according to different design considerations. Referring to the words “up” or “down” that describe the relationship between components in the text, it is well known in the art and should be clearly understood that these words refer to relative positions that can be inverted to obtain a same structure, and these structures should therefore not be precluded from the scope of the claims in the present invention.

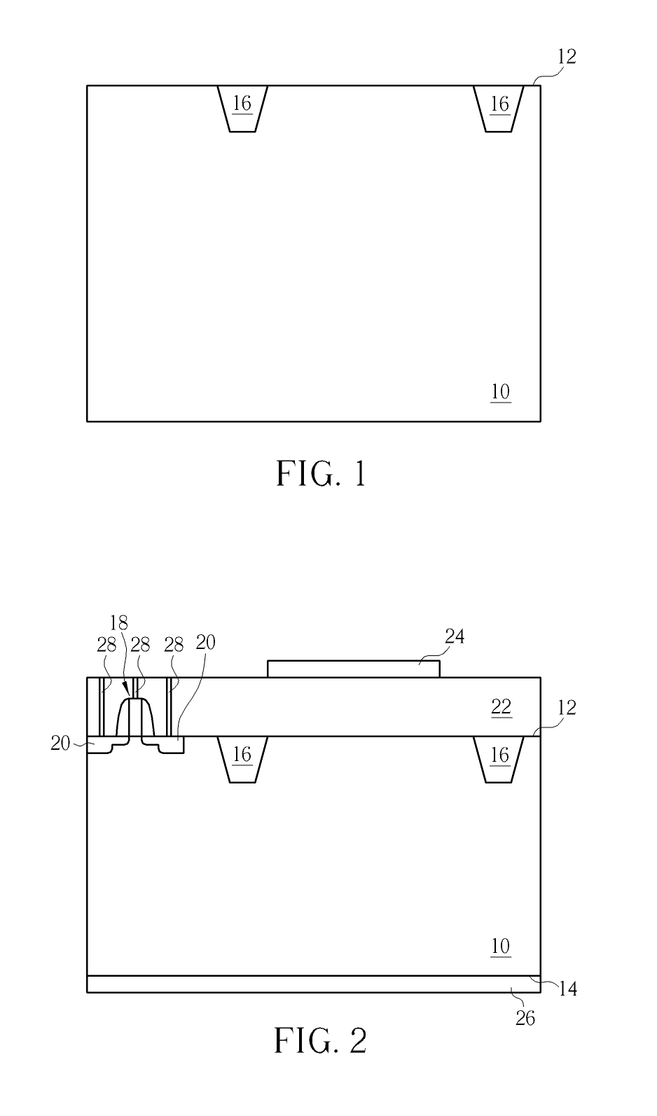

Please refer to FIGS. 1-7. FIGS. 1-7 are schematic, cross-sectional view diagrams showing a method for fabricating a semiconductor device with a TSV according to the first preferred embodiment of the present invention. As shown in FIG. 1, at first, a substrate 10 is provided, such as silicon substrate, an epitaxial silicon substrate, a silicon germanium substrate, a silicon carbide substrate or a silicon-on-insulator (SOI), wherein the substrate 10 has a front surface 12 and a back surface 14. In this embodiment, the substrate 10 is a bulk silicon substrate, but not limited thereto. An N-well or a P-well is then formed in the substrate 10 (not shown), and a plurality of STI (shallow trench isolations) 16 is then formed in the substrate 10.

As shown in FIG. 2, at least one gate structure 18 is formed on the substrate 10, and a S/D region 20 is then formed in the substrate 10 wherein the S/D region 20 is located at both sides of the gate structure 18. The gate structure 18 includes a polysilicon gate, a metal gate or a dummy gate, but not limited thereto. The method for fabricating the gate structure 18, the S/D region 20, or a salicide (not shown) layer disposed on the S/D region 20 are well known to persons of ordinary skills in the art and the details will not be described here. An ILD (inter layer dielectric) 22 is deposited on the gate structure 18 and the front surface 12, an inter metal dielectric (IMD) process is then carried out to form a plurality of IMD (inter metal dielectric) (not shown) and a plurality of metal traces which are disposed in each IMD (not shown) on the ILD 22.

To simplify the description, FIG. 2 only illustrates a metal trace 24 formed on the ILD 22, which corresponds to a TSV formed in following steps and neglects others IMD and others metal traces disposed in the IMD. A bottom surface of the metal trace 24 can directly contact the TSV; hence the TSV can be electrically connected to other components through the metal traces disposed in the IMD. Besides, a contact etching stop layer (CESL) (not shown) may be selectively formed between the ILD 22 and the substrate 10 to cover the gate structure 18 and the S/D region 20, and a plurality of contact plugs 28 is disposed on the gate structure 18 and the S/D region 20 to electrically connected to the metal traces (not shown) disposed in the IMD above the ILD 22. In the present invention, the materials of the metal trace 24, the contact ring 26 and the contact plug 28 can be selected from the group of copper (Cu), aluminum (Al), tungsten (W), titanium (Ti), titanium nitride (TiN), tantalum (Ta) or tantalum nitride (TaN), but not limited thereto.

After the IMD process is carried out and a bonding pad disposed on the IMD is formed on the front surface 12, the back surface 14 of the substrate 10 is grinded to thin down the substrate 10, a cap layer 26 is then formed on the back surface 14, the cap layer 26 comprises insulator materials such as SiO₂, SiN, SiC or SiON, but not limited thereto. In this invention, the cap layer 26 comprises SiN.

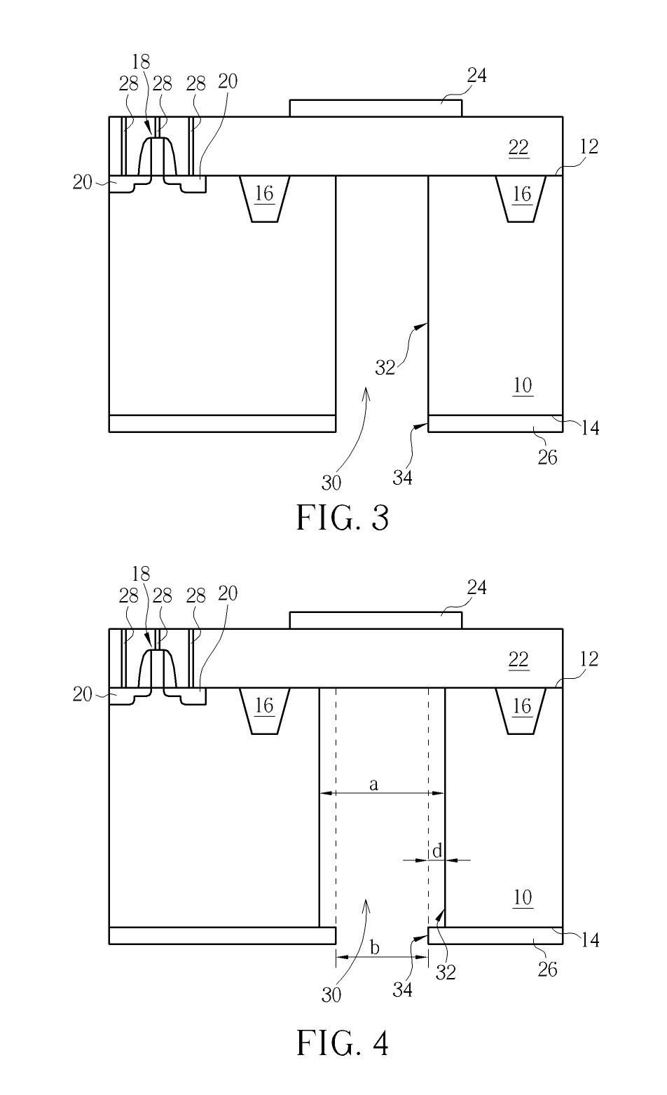

As shown in FIG. 3, an opening 30 is formed on the back surface 14 through a photo-etching process, wherein the opening 30 is used to define the location of the TSV which is formed in following steps. The opening 30 penetrates the substrate 10 and the cap layer 26. Besides, a bottom of the opening 30 is stopped on a bottom of the ILD 22. The opening 30 has a substrate sidewall 32 and a cap layer sidewall 34.

It is worth noting that, after the opening 30 is formed on the back surface 14, as shown in FIG. 4, a pull back process is carried out to uniformly extend the substrate sidewall 32. In other words, the diameter “a” of the opening 30 inside substrate sidewall 32 is larger than the diameter “b” of the opening 30 inside the cap layer sidewall 34. Hence, the cap layer sidewall 34 juts out beyond the substrate sidewall 32 with a predetermined distance “d”, wherein d=(a−b)/2, The pull back process includes a wet etch process, e.g. hydrofluoric acid mixed with ethylene glycol or an isotropic plasma etch process to selectively etch the cap layer 26 and the substrate 10, but it is not limited thereto.

In addition, in this embodiment, after the opening 30 is formed, the substrate sidewall 32 is then extended through the pull back process, but the present invention is not limited thereto. In other words, the present invention may adjust the etching recipes to form the opening 30 and extends the substrate sidewall 32 simultaneously through an etching process.

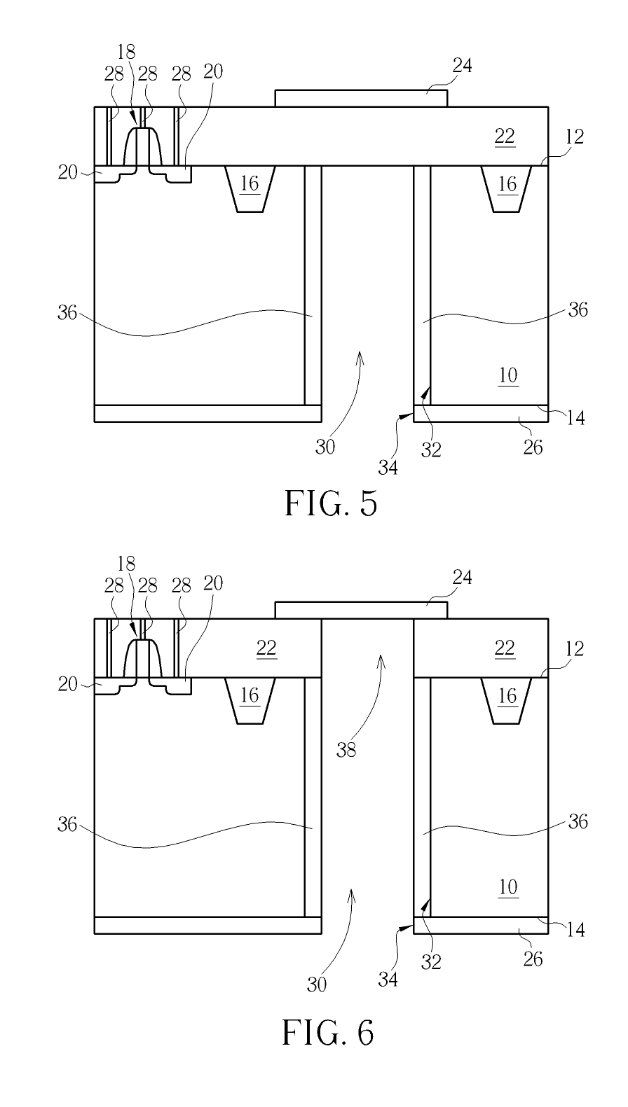

As shown in FIG. 5, a liner 36 is formed on the back surface 14 and in the opening 30 to cover the bottom surface and the sidewalls of the opening 30, the liner 36 is a single layer structure such as SiN or SiO2, or multi-layer structure, but not limited thereto. It is worth noting that, the liner 36 is selectively formed on the substrate sidewall 32 but not formed on the cap layer sidewall 34 through a thermal oxidation process or an electro-chemical process. For example, the liner 36 is only disposed on a conductive material like the substrate sidewall 32 through an electro-chemical process. In other words, the liner 36 is not disposed on a non-conductive material like the cap layer sidewall 34. Because of the predetermined distance “d” between the substrate sidewall 32 and the cap layer sidewall 34, a predetermined space is formed on the substrate sidewall 32, and the liner 36 is formed in the predetermined space. The liner 36 then overlaps the cap layer 26 along a width; a “corner” won't therefore be formed at the interface of the liner 36 and the cap layer 26 causing current leakage. In this embodiment, the overlapped width of the liner 36 and the cap layer 26 is preferably larger than 10 nm to obtain better sealing performances at the interface. Besides, after the liner 36 is formed in the predetermined space, the sidewall of the liner 36 can be aligned with the cap layer sidewall 34 or not. In other words, the sidewall of the liner 36 may jut out beyond the cap layer sidewall 34, or on the contrary, the cap layer sidewall 34 juts out beyond the sidewall of the liner 36. However, whether the sidewall of the liner 36 is aligned with the cap layer sidewall 34 or not, the overlapped width between the liner 36 and the cap layer 26 is preferably larger than 10 nm.

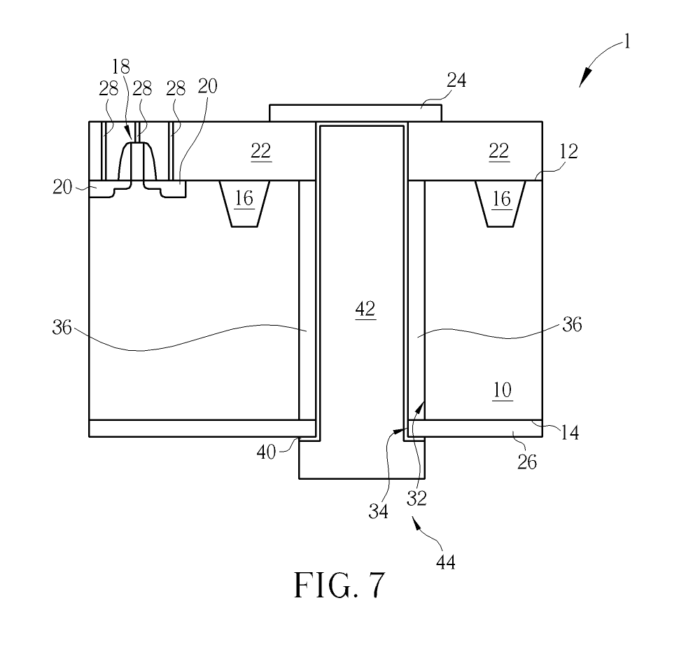

As shown in FIG. 6-7, an etching process is then performed on the opening 30 again to form a TSV hole 38 and a bottom of the TSV hole 38 is stopped on a bottom of the metal trace 24. Afterwards, a barrier layer 40 is selectively formed in the TSV hole 38, a conductive layer 42 is then formed in the TSV hole 38 and on the back surface 14 to form a TSV 44, wherein the barrier layer 40 includes Ti, TiN, Ta or TaN, but not limited thereto, the conductive layer 42 includes metals of high conductivity such as Copper (Cu). The manufacturing method for forming the conductive layer 42 comprises the following steps: first, rrra Cu seed layer can be formed on the barrier layer 40, and a backside-bump process is carried out to form a patterned photo resistor (not shown). After electroplating the Cu layer on the Cu seed layer, the patterned photo resistor is removed, and a semiconductor device with a TSV is completed. This way, a semiconductor device 1 of the present invention includes a substrate 10 with a front surface 12 and a back surface 14, an ILD 22 disposed on the front surface 12; a cap layer 26 disposed the back surface 14, a TSV 44 penetrating the cap layer 26, the substrate 10 and the ILD 22, wherein the TSV 44 has a cap layer sidewall 34 and a substrate sidewall 32, the cap layer sidewall 34 juts out beyond the substrate sidewall 32 with a predetermined distance; a liner 36 disposed on the substrate sidewall 32, and the liner 36 overlaps parts of the cap layer 26. The device further comprises at least one gate structure 18 disposed in the ILD 22, and the gate structure 18 includes a metal gate, a polysilicon gate or a dummy gate.

There is an issue in conventional TSV process: when the substrate sidewall is aligned with the cap layer sidewall, and a liner is then selectively formed on the substrate sidewall through an electro-chemical process, the liner will jut out beyond the cap layer sidewall and form a corner at the interface of liner and the cap layer sidewall. Said corner may further increase the leakage current of the TSV. In addition, the TSV usually connects others semiconductor components, such as transistors, memories, inductors or resistors. When the TSV acts as a power pin, the massive current transmitted through the TSV will cause serious electromagnetic interferences (EMI) to the adjacent components, such as the gate structure.

A specific feature of the present invention is to pull back the substrate sidewall 32 during the process forming the opening 30 before the TSV hole 38 is formed, which makes the diameter “a” of the opening 30 inside the substrate sidewall 32 larger than the diameter “b” of the opening 30 inside the cap layer sidewall 34. When the liner 36 is formed on the substrate sidewall 32, the liner 36 is substantially aligned with the cap layer sidewall 34, and no corner will therefore be formed at the interface of the cap layer sidewall 34 and the liner, thereby avoiding current leakage. This furthermore significantly improves the yield of the manufacturing process.

It can be noted that the present invention is not necessarily only applied during via-last processes, it also may be obtained through via-middle processes or via-first processes, or others semiconductor device where a corner is likely to be formed. If the following conditions are satisfied, any process should be comprised in the scope of the present invention: A pull back process is used to keep a predetermined distance between the substrate sidewall and the cap layer sidewall, and a liner is selectively formed on the substrate sidewall.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, with a front surface and a back surface;
an ILD (inter layer dielectric) disposed on the front surface;
a cap layer disposed on the back surface;
a TSV (through silicon via) penetrating the cap layer, the substrate and the ILD, wherein the TSV has a cap layer sidewall and a substrate sidewall, and the cap layer sidewall juts out beyond the substrate sidewall with a predetermined distance; and
a liner disposed on the substrate sidewall in the TSV, wherein the liner overlaps with parts of the cap layer.

2. The semiconductor device of claim 1, further comprising a metal trace disposed on a surface of the ILD.

3. The semiconductor device of claim 1, further comprising a conductive layer disposed in the TSV.

4. The semiconductor device of claim 1, wherein a sidewall of the liner is aligned with the cap layer sidewall.

5. The semiconductor device of claim 1, wherein a sidewall of the liner juts out beyond the cap layer sidewall.

6. The semiconductor device of claim 1, wherein the cap layer sidewall juts out beyond a sidewall of the liner.

7. The semiconductor device of claim 1, wherein the liner is only disposed in the substrate.

8. The semiconductor device of claim 1, wherein an overlapped width between the liner and the cap layer is larger than 10 nm.

9. The semiconductor device of claim 1, further comprising a barrier layer disposed in the TSV.

10. The semiconductor device of claim 1, further comprising a gate structure disposed in the ILD, wherein the gate structure includes a metal gate, a polysilicon gate or a dummy gate.

11. A manufacturing method of a semiconductor device, comprising:
providing a substrate, with a front surface and a back surface;
forming an ILD (inter layer dielectric) on the front surface;
forming a cap layer on the back surface;
forming an opening on the back surface of the substrate penetrating the cap layer and the substrate, wherein the opening has a cap layer sidewall and a substrate sidewall, and the cap layer sidewall juts out beyond the substrate sidewall with a predetermined distance;
forming a liner selectively on the substrate sidewall, and the liner overlaps with parts of the cap layer;
etching the ILD through the opening to form a TSV hole penetrating the ILD; and
forming a conductive layer in the TSV hole.

12. The manufacturing method of a semiconductor device of claim 11, wherein an overlapped width between the liner and the cap layer is larger than 10 nm.

13. The manufacturing method of a semiconductor device of claim 11, further comprising forming a metal trace disposed on a surface of the ILD.

14. The manufacturing method of a semiconductor device of claim 13, wherein the TSV hole exposes the metal trace.

15. The manufacturing method of a semiconductor device of claim 13, further comprising forming a barrier layer disposed in the TSV.

16. The manufacturing method of a semiconductor device of claim 11, further comprising forming a gate structure disposed in the ILD.

17. The manufacturing method of a semiconductor device of claim 16, wherein the gate structure includes a metal gate, a polysilicon gate or a dummy gate.

18. The manufacturing method of a semiconductor device of claim 11, wherein the opening exposes the ILD.

19. The manufacturing method of a semiconductor device of claim 11, wherein the liner is formed on the substrate through an electro-chemical process or an ALD (atom layer deposition).

20. The manufacturing method of a semiconductor device of claim 11, further forming a STI (shallow trench isolation) in the substrate.
